(19) United States
(12) Patent Application Publication
(10) Pub. No.: US 2017/0085227 A1
(43) Pub. Date: Mar. 23, 2017

(54) HIFI AUDIO TUBE AMPLIFIER

(71) Applicant: Sennheiser electronic GmbH & Co. KG, Wedemark (DE)

(72) Inventors: Dirk Krätzer, Hannover (DE); Andre Grandt, Wedemark (DE); Axel Grell, Burgdorf (DE); Alexander Grimm, Wunstorf (DE)

(73) Assignee: Sennheiser electronic GmbH & Co. KG, Wedemark (DE)

(21) Appl. No.: 15/267,382

(22) Filed: Sep. 16, 2016

(30) Foreign Application Priority Data
Sep. 21, 2015 (DE) 102015218066.2

(51) Int. Cl. H03F 1/28; H03F 3/181

(52) U.S. Cl. CPC H03F 1/28; H03F 3/181; H03F 2200/447

(57) ABSTRACT

A casing unit is provided that includes a cylindrical peripheral wall portion of quartz or glass, a cover of metal, and a fixing unit configured to fix the casing unit in or to a housing of a hi-fi tube amplifier. Also provided is a hi-fi audio tube amplifier that includes a plurality of tubes configured to amplify audio signals, and a plurality of the afore-mentioned casing units. Each casing unit encloses one tube of the plurality tubes at three sides, and the fixing unit of each casing unit is configured to fix the respective casing unit in or to a housing of the hi-fi audio tube amplifier.

The present application claims priority from German Patent Application No. 10 2015 218 066.2 filed on Sep. 21, 2015, the disclosure of which is incorporated herein by reference in its entirety.

### FIELD OF THE INVENTION

It is noted that citation or identification of any document in this application is not an admission that such document is available as prior art to the present invention.

The present invention concerns a hi-fi audio tube amplifier.

Audio amplifiers with tubes are nowadays used only in guitar amplifiers or hi-fi amplifiers. In that case the tubes serve to amplify the audio signals which occur as electrical signals.

In the German patent application from which priority is claimed the following documents were cited as state of the art by the German Patent and Trade Mark Office: Harmonielehre. in: LP-magazin, January 2014, 50-53, www.reussenzehn.de, U.S. Pat. No. 2,939,051 A, GB 1 077 512 A and U.S. Pat. No. 2,499,589 A.

### SUMMARY OF THE INVENTION

An object of the present invention is to provide a hi-fi tube amplifier which permits improved amplification of an audio signal.

Thus there is provided a hi-fi audio tube amplifier having a plurality of tubes for amplifying audio signals and a plurality of casing units which surround a respective one of the tubes. The casing units are of a cylindrical configuration and each surround a respective tube. The tubes are thereby in particular dust-tightly enclosed.

The casing unit can have a cylindrical peripheral wall portion of quartz glass or glass. Optionally an end of the casing unit is fixed in or to a housing. That can be effected for example by a screw or bayonet connection. Optionally a seal can be provided at that end of the casing unit.

According to the invention therefore the casing unit dust-tightly encloses the tube. That can provide for decoupling of ambient noises from acting on the tubes. In particular air-borne sound generated by the ambient noises can be kept away from the tubes by the casing unit. In that way it is possible to address the microphony vulnerability of the tubes. Microphony vulnerability of a tube means that mechanical vibration of the tube has an unwanted effect on the electrical output signal of the tube.

According to the invention there is provided a tube amplifier having a plurality of casing units which have a cylindrical peripheral wall portion of glass or quartz, a cover (for example of metal) at one end and an open end which can be fixed in or to a housing of an amplifier so that the casing unit completely surrounds the tube and decouples it from external noise.

Optionally the cover can be made from metal to be able to dissipate the waste heat of the tube. That is effected by convection. Optionally the cover can be made from brass.

The hi-fi audio tube amplifier according to the invention provides high-quality quartz bulbs which enclose the (vacuum) tubes and thus eliminate any influence of sound which is transmitted by way of the air.

The tube amplifier according to the invention has 99.9% silver-plated copper cables which provide for optimum conductivity in order to transmit the signal for example to a headphone.

The headphone which is optionally connected to the tube amplifier has an amplifier stage within the headphone in order to afford ultra-high pulse fidelity and an efficiency which is 200% higher in comparison with other headphones available at the present time for sound reproduction.

### BRIEF DESCRIPTION OF THE DRAWINGS

FIG. 1 shows a diagrammatic view of a hi-fi audio tube amplifier according to the invention.

FIG. 2 shows an exploded view of a tube and a casing unit according to the invention.

### DETAILED DESCRIPTION OF EMBODIMENTS

It is to be understood that the figures and descriptions of the present invention have been simplified to illustrate elements that are relevant for a clear understanding of the present invention, while eliminating, for purposes of clarity, many other elements which are conventional in this art. Those of ordinary skill in the art will recognize that other elements are desirable for implementing the present invention. However, because such elements are well known in the art, and because they do not facilitate a better understanding of the present invention, a discussion of such elements is not provided herein.

The present invention will now be described in detail on the basis of exemplary embodiments.

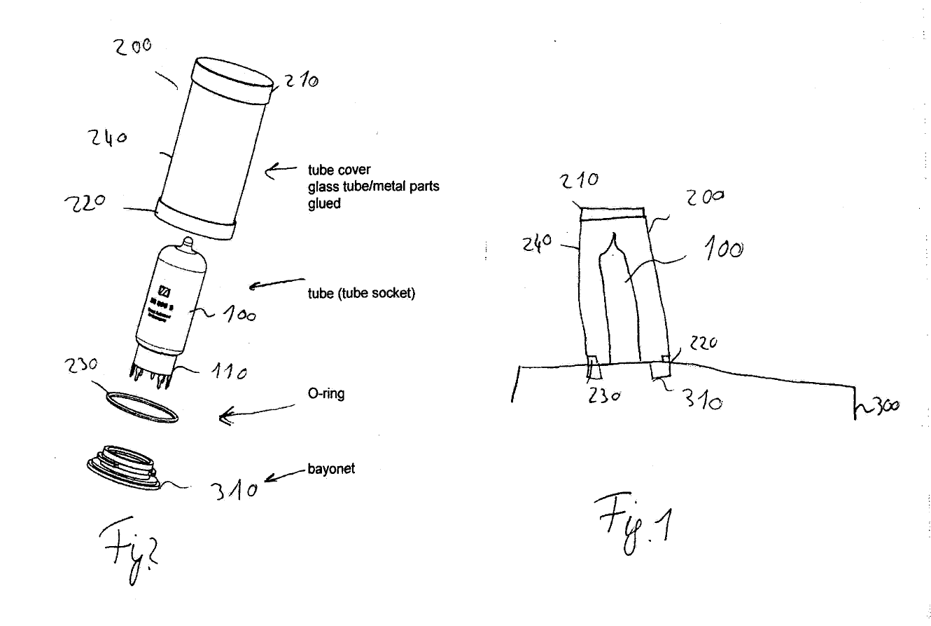

FIG. 1 shows a diagrammatic view of a hi-fi audio tube amplifier 10 according to the invention. The hi-fi tube amplifier 10 has a housing 300 with a plurality of (vacuum) tubes 100 for amplifying the audio signal. A casing unit 200 is provided around each vacuum tube 100. The casing unit 200 has a cylindrical peripheral wall portion 240 of glass or quartz, a cover 210 for example of metal and at its open end a fixing unit 220 for fixing the casing unit 200 to a housing 300 of the amplifier. The fixing unit 220 can represent a screw connection or a bayonet connection. Optionally a seal 230 can be provided in the region of the fixing unit 220.

In that way the vacuum tube 100 is completely surrounded at three sides by the casing unit 200. When the casing unit 200 is fixed in or to the housing by means of the fixing unit 220 then the tube 100 is dust-tightly enclosed within the casing unit 200.

FIG. 2 shows an exploded view of a tube and a casing unit according to the invention. The tube 100 has a tube socket 110 and is fixed on a circuit board in the housing 300 of the audio amplifier. A casing unit 200 is placed over the tube 100. The casing unit 200 has a cylindrical peripheral wall portion 240 of quartz or glass and a cover 110 for example of metal. The casing unit 100 also has a fixing unit 220 which can be fixed in a bayonet unit 310 in the housing.

The invention concerns an audio amplifier, in particular a headphone amplifier having a plurality of tubes as part of the amplifier circuit. The tubes can be screened from ambient sound by means of the casing unit 200 to reduce disturbances due to microphony.

Optionally the cover 210 can be glued on the wall portion 240.

In that case the cover 210 serves as a cooling unit in order to dissipate heat produced by operation of the tube within the casing unit 200.

Mechanical vibration of the tube which is caused by ambient noise can be considerably reduced by the casing unit.

While this invention has been described in conjunction with the specific embodiments outlined above, it is evident that many alternatives, modifications, and variations will be apparent to those skilled in the art. Accordingly, the preferred embodiments of the invention as set forth above are intended to be illustrative, not limiting. Various changes may be made without departing from the spirit and scope of the inventions as defined in the following claims.

1. A hi-fi audio tube amplifier comprising:
a plurality of tubes configured to amplify audio signals; and
a plurality of casing units, each casing unit of the plurality of casing units enclosing one tube of the plurality tubes at three sides;
wherein each casing unit comprises:
a cylindrical peripheral wall portion of glass or quartz;
a cover of metal; and
a fixing unit configured to fix the casing unit in or to a housing of the hi-fi audio tube amplifier.

2. The hi-fi tube amplifier as set forth in claim 1, further comprising:
a sealing ring that is arranged in a region of the fixing unit of at least one casing unit of the plurality of casing units.

3. A casing unit for a hi-fi audio tube amplifier the casing unit comprising:
a cylindrical peripheral wall portion of quartz or glass;
a cover of metal; and
a fixing unit configured to fix the casing unit in or to a housing of a hi-fi tube amplifier.
